(19) United States
(12) Patent Application Publication
(10) Pub. No.: US 2015/0003172 A1
(43) Pub. Date: Jan. 1, 2015

(54) MEMORY MODULE INCLUDING BUFFER CHIP CONTROLLING REFRESH OPERATION OF MEMORY DEVICES

(71) Applicants: SUA KIM, SEONGNAM-SI (KR); CHUL-WOO PARK, YONGIN-SI (KR); MU-JIN SEO, SEOUL (KR)

(72) Inventors: SUA KIM, SEONGNAM-SI (KR); CHUL-WOO PARK, YONGIN-SI (KR); MU-JIN SEO, SEOUL (KR)

(21) Appl. No.: 14/299,548

(22) Filed: Jun. 9, 2014

Related U.S. Application Data
(60) Provisional application No. 61/839,400, filed on Jun. 26, 2013.

(30) Foreign Application Priority Data
Sep. 13, 2013 (KR) 10-2013-0110621

(51) Int. Cl. G11C 11/406

(52) U.S. Cl. CPC G11C 11/40607; G11C 11/40626; G11C 11/40615
USPC 365/189.05; 365/222

(57) ABSTRACT

Provided is a memory module including a buffer chip controlling refresh operations. The buffer chip issues a hidden refresh command controlling refresh operations for the memory chips, and outputs a wait signal indicating that the memory chips are in refresh.

### CROSS-REFERENCE TO RELATED APPLICATIONS

This application claims the benefit of Korean Patent Application No. 2013-0110621 filed on Sep. 13, 2013 and U.S. Provisional Application No. 61/839,400 filed on Jun. 26, 2013, the collective subject matter of which is hereby incorporated by reference.

### BACKGROUND

The inventive concept relates generally to memory systems. More particularly, embodiments of the inventive concept provide improved memory system performance by controlling the refresh operation of a memory chip using a buffer chip mounted on a memory module.

Certain memory devices such as the dynamic random access memory (DRAM) perform a refresh operation in order to maintain stored data. As the data storage capacity of contemporary DRAMs increases, so too does the refresh time tRFC for the constituent memory cells. As the refresh time tRFC of the individual memory cells increases, the time taken to refresh all memory cells of a DRAM also increases. During execution of a refresh operation, data access (e.g., read and write operations) to the DRAM is blocked. Thus, the overall performance of memory systems including DRAM(s) having extended refresh periods is degraded. In order to improve the performance of contemporary and emerging memory systems, improved methods that effectively control the execution of a refresh operation in a DRAM are required.

### SUMMARY

Embodiments of the inventive concept provide a buffer chip controlling a refresh operation for a memory chip and a memory module including this type of buffer chip.

According to an aspect of the inventive concept, there is provided a memory module operating in response to commands communicated from a memory controller, the memory module including; a memory chip mounted on a module substrate, and a buffer chip mounted on the module substrate, wherein the buffer chip provides a hidden refresh command controlling execution of a refresh operation by the memory chip and during execution of the refresh operation provides a wait signal indicating execution of the refresh operation to the memory controller, wherein the refresh operation is executed by the memory chip in response to the hidden refresh command independent of command communicated from the memory controller.

According to an aspect of the inventive concept, there is provided a memory system, including; a memory module including a buffer chip and memory chips mounted on a module substrate, and a memory controller that controls execution of read/write operations by the memory chips in response to commands communicated from the memory controller to the buffer chip, wherein the buffer chip provides a hidden refresh command controlling execution of refresh operations by the memory chips, and during execution of the refresh operations the buffer chip provides a wait signal indicating execution of the refresh operations to the memory controller, the refresh operation being executed by the memory chips in response to the hidden refresh command independent of commands communicated from the memory controller.

According to an aspect of the inventive concept, there is provided a memory module including; memory chips mounted on a module substrate, and a buffer chip mounted on the module substrate and configured to communicate a hidden refresh command controlling refresh operations for the memory chips, wherein refresh of a weak cell row among the memory chips is performed in accordance with a period that is shorter than a normal refresh period associated with the refresh operations, and the refresh operation is executed by the memory chips in response to the hidden refresh command independent of commands communicated from the memory controller.

### BRIEF DESCRIPTION OF THE DRAWINGS

Embodiments of the inventive concept will be more clearly understood from the following detailed description taken in conjunction with the accompanying drawings in which:

FIG. 1 is a block diagram of a memory module including a buffer chip according to an embodiment of the inventive concept;

FIGS. 2A, 2B and 2C are respective diagrams illustrating bus paths and wiring arrangements for a memory module according to certain embodiments of the inventive concept;

FIG. 3 is a block diagram further illustrating in one example a buffer chip according to an embodiment of the inventive concept;

FIG. 4 is a diagram further illustrating a memory chip performing a hidden refresh via a buffer chip according to an embodiment of the inventive concept;

FIG. 5 is a block diagram illustrating in one example the refresh address generation unit of FIG. 4;

FIG. 6 is a block diagram illustrating in another example the refresh address generation unit of FIG. 4;

FIG. 7 is a general flowchart summarizing one method of refreshing a memory chip by using a buffer chip according to an embodiment of the inventive concept;

FIG. 8 is a flowchart summarizing a method of refreshing a memory chip according to another embodiment of the inventive concept;

FIG. 9 is a flowchart summarizing a method of refreshing a memory chip by using a buffer chip according to another embodiment of the inventive concept;

FIG. 10 is a flowchart summarizing a method of refreshing a memory chip by using a buffer chip according to still another embodiment of the inventive concept;

FIGS. 11, 12, 13 and 14 are respective timing diagrams illustrating refresh operation(s) of a memory chip by using a buffer chip according to certain embodiments of the inventive concept;

FIG. 15 is a block diagram of a mobile system to which a buffer chip and a memory chip according to certain embodiments of the inventive concept may be applied; and

FIG. 16 is a block diagram of a computing system to which a memory module including a memory chip and a buffer chip according to certain embodiments of the inventive concept may be applied.

### DETAILED DESCRIPTION

In order to fully understand certain operational advantages of the inventive concept and objects to be attained by various embodiments of the inventive concept, the accompanying drawings illustrating exemplary embodiments of the inventive concept and details described in the accompanying drawings should be referred to.

The inventive concept now will be described more fully hereinafter with reference to the accompanying drawings in which selected embodiments of the inventive concept are shown. The inventive concept may, however, be embodied in many different forms and should not be construed as being limited to only the illustrated embodiments. Rather, these embodiments are provided so that this disclosure will be thorough and complete, and will fully convey the scope of the inventive concept to one of ordinary skill in the art. As the inventive concept allows for various changes and numerous embodiments, particular embodiments will be illustrated in the drawings and described in detail in the written description. However, this is not intended to limit the inventive concept to particular modes of practice, and it is to be appreciated that all changes, equivalents, and substitutes that do not depart from the spirit and technical scope of the inventive concept are encompassed in the inventive concept. Throughout the written description and drawings, like reference numbers and labels refer to like or similar elements.

The terminology used herein is for the purpose of describing particular embodiments only and is not intended to be limiting of exemplary embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, components, or combinations thereof but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items. Expressions such as “at least one of” when preceding a list of elements, modify the entire list of elements and do not modify the individual elements of the list.

A memory cell of a semiconductor memory device, such as DRAM, operates to record data according to electrical charge stored on a cell capacitor. The charge storage capacity of certain semiconductor memory devices (e.g., the DRAM) provide only a finite data retention period that has been continuously reduced as the integration density of contemporary semiconductor devices has increased. Thus, as the capacitance of constituent cell capacitors has decreased, the bit error rate (BER) for the memory cell has increased, thereby reducing the reliability of stored data. To prevent the loss of stored data over time due to electrical charge dissipation, DRAMs perform a so-called “refresh operation.” The use of different refresh operations is conventionally appreciated and is understood to be required in order to maintain data stored by certain types of memory cells.

A predetermined time interval between refresh operations applied to a DRAM is commonly referred to as a “refresh cycle” (tREF). The specifications that define the operation of contemporary DRAMs include at least one refresh cycle tREF. For example, a refresh cycle tREF refreshing 8K memory cell rows for 64 ms, or a refresh cycle tREF refreshing 4K memory cell rows for 32 ms may be specified.

It should further be noted that as the data storage capacity of a DRAM increases, the “refresh current consumption” (i.e., the electrical current consumed during a refresh operation sufficient to refresh all of the memory cell of a DRAM) increases. In some instances, an electric power stabilizing operation may accompany the refresh power consumption. This requirement may further increase the refresh time tRFC. And as has been noted above, during the refresh time tRFC, normal operations such as read operations and write operations directed to memory cells of a DRAM-being-refreshed will be blocked.

Those skilled in the art are familiar with a great variety of “memory modules”. A memory module in its most common forms includes a number of semiconductor memory chips (e.g., DRAMs) mounted on a module substrate (e.g., a printed circuit board) and controlled by a memory controller. The operative combination of memory controller and memory module(s) may be understood as a “memory system” of sorts. Research and development efforts into different types and operative forms of memory module have realized a large number of high-operating-speed, high-data-capacity memory systems. A memory controller may not simultaneously accesses a DRAM of a memory module for both normal and refresh operations. Accordingly, the memory controller must monitor whether or not a DRAM is “accessible” in relation to an executed refresh operation.

With the foregoing in mind, certain embodiments of the inventive concept provide a memory module that is capable of controlling the execution of refresh operations for constituent DRAMs of the memory module so as to improve the overall performance of the memory system.

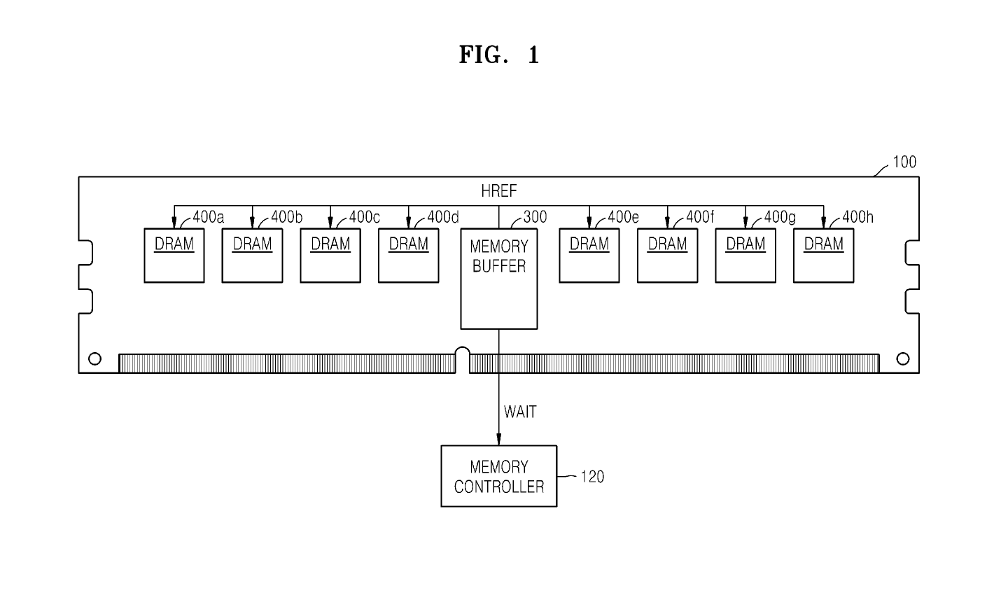

FIG. 1 is a block diagram of a memory module 100 according to an embodiment of the inventive concept.

Referring to FIG. 1, the memory module 100 includes a plurality of memory chips 400a through 400h and a buffer chip 300. The memory module 100 may be (e.g.,) a load reduced dual in-line memory module (LR-DIMM) or other type of memory module.

The memory module 100 may be connected to a memory controller 120 via a data bus configured to send/receive data to/from the memory chips 400a through 400h, and a control bus configured to communicate command (CMD), address (ADDR), and/or control signals (Ctrl) including clock signals, (hereafter, singularly or collectively in any reasonable combination “C/A signals”) that control the execution of read/write operations, etc. The memory controller 120 may be directly connected to a corresponding central processing unit (CPU), or be provided as a functional part of a CPU. Hereafter, the various operative combinations of the memory controller 120 and memory module 100 will be termed a memory system.

The buffer chip 300 receives C/A signals and/or data (DQ) from the memory controller 120, and thereafter provides C/A signals and/or data to the memory chips 400a through 400h. For purposes of distinction C/A signals provided by the memory controller 120 to the buffer chip will be termed “external C/A signals”, while the C/A signals provided by the memory controller 120 to the buffer chips 4000a though 400h will be termed “internal C/A signals”. In this arrangement, the memory controller 120 serves as an external interface of sorts for the memory module 100 by driving data loads to/from the buffer chip 300.

The buffer chip 300 may receive an “external refresh command” from the memory controller 120, and may in response to an external refresh command be used to control the execution of refresh operation(s) for the memory chips 400a through 400h. The refresh operation indicated by an external refresh operation may be an auto-refresh operation, a self-refresh operation, etc. The auto-refresh operation is an operation generating a refresh row address in response to a refresh command (REF) periodically applied to refresh a particular memory cell row corresponding to the refresh row address. The self-refresh operation is an operation causing entry into a self-refresh mode in response to a self-refresh enter command (SRE), and refreshing memory cell rows periodically using a built-in timer used during the self-refresh mode.

The buffer chip 300 may issue a “hidden refresh command” (HREF) that controls execution of refresh operations by the memory chips 400a through 400h, independent of any external refresh command received from the memory controller 120. That is, the buffer chip 300 may issue one or more hidden refresh command(s) to one or more of the memory chips 400a through 400h independent of an externally received refresh command, such as an auto-refresh command or a self-refresh command provide by the memory controller 120. A hidden refresh command may be provided to the memory chips 400a through 400h with a bank address, and the memory chips 400a through 400h may generate a refresh row address for a bank corresponding to the bank address in response to the hidden refresh command. Alternately, a hidden refresh command may be provided to the memory chips 400a through 400h with a row address, and the memory chips 400a through 400h may refresh a memory cell row corresponding to the refresh row address.

When receiving an active command (ACT) from the memory controller 120 while the memory chips 400a-400h are performing the refresh operation in response to a hidden refresh command, the buffer chip 300 will provide a wait signal (WAIT) to the memory controller 120 indicating that the memory chips 400a-400h are busy performing a refresh operation. Thus, the memory chips 400a-400h may not perform the operation indicated by the active command received from the memory controller 120 during the refresh operation. Accordingly, the generated wait signal indicates this standby state with respect to a received active command.

In order to communicate the wait signal provided by the buffer chip 300 to the memory controller 120, an output (or input/output) pin may be allocated (or newly provided) on the memory module 100. Assuming a case where one or more new pin(s) is allocated, the wait signal may be communicated serially to the memory controller 120 using one pin, or in parallel using a plurality of pins.

Upon receiving the wait signal provided by the buffer chip, the memory controller 120 may reissue one or more active command(s) delayed by the wait signal following a predetermined time delay. In this regard, the memory controller 120 will operationally expect that the completed execution of any operations assigned to the memory chips 400a through 400h before the wait signal was received until after the predetermined time delay has elapsed.

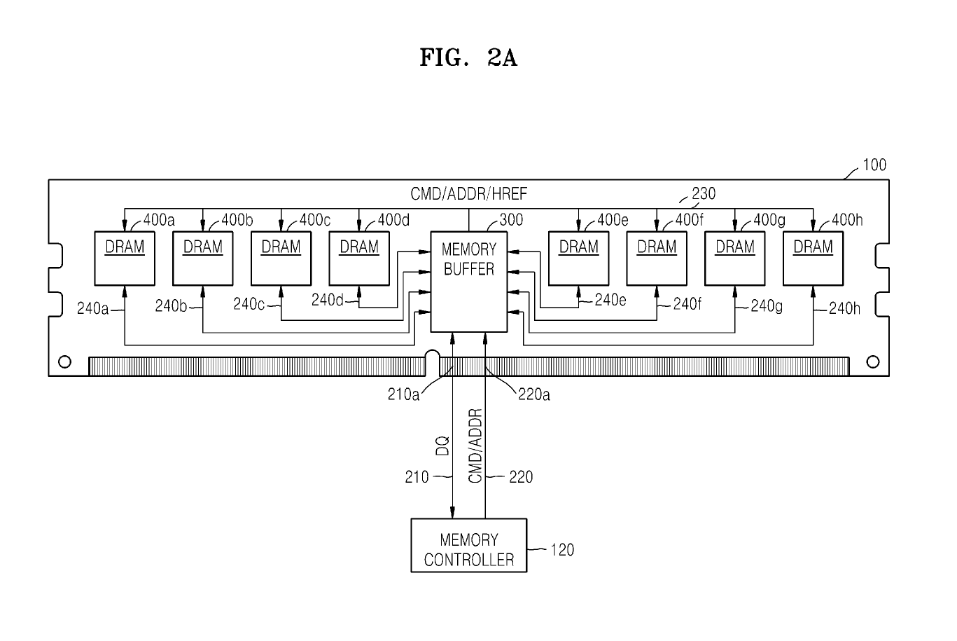

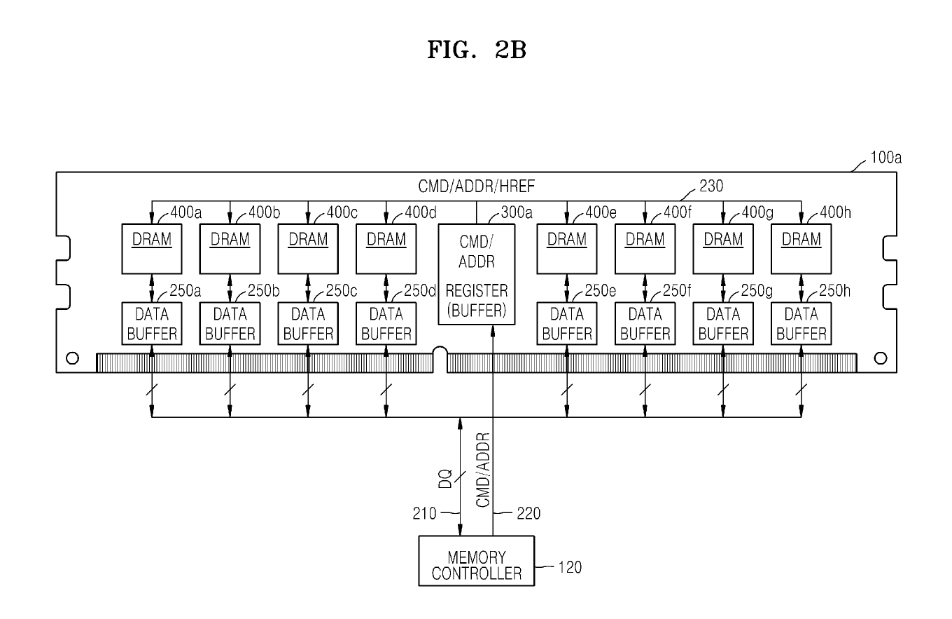

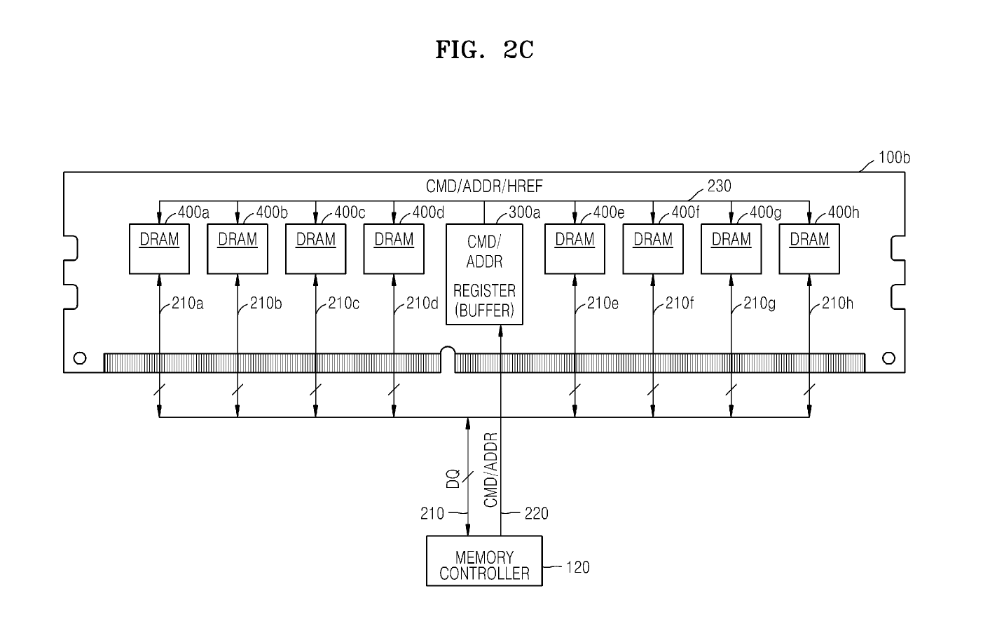

FIGS. 2A, 2B and 2C are respective diagrams illustrating exemplary bus paths and/or wiring arrangements for the memory module 100 according to certain embodiments of the inventive concept.

Referring to FIG. 2A, the memory module 100 may be connected to the memory controller 120 via a separate data bus (DQ) and a control bus (e.g., a command/address or CMD/ADDR) bus 220. The memory module 100 may be inserted into a socket connector of a larger memory system or computational system. Electric connectors (or pins) 210a and 220a of the memory module 100 may be connected to electric contacts of the socket connector. The electric connectors 210a and 220a and the buses 210 and 220 connected to the electric contacts allow direct access to the buffer chip 300 and indirect access to the memory chips 400a-400h of the memory module 100. The data bus 210 includes at least one data (DQ) line, and the control bus 220 includes at least one of a command (CMD) line and/or address (ADDR) line.

The data bus 210 and control bus 220 are directly connected to the buffer chip 300 via the respective socket/pin and bus signal line arrangements. In turn, the buffer chip 300 is connected to the respective memory chips 400a-400h via at least a commonly-connected first bus 230 and separately connected second buses 240a through 240h from specified ports of the buffer chip 300 to corresponding ports of the memory chips 400a-400h. The buffer chip 300 may be used to transfer a received command and/or address received from the memory controller 120 via the control bus 220 to the respective memory chips 400a-400h via the first bus 230. The buffer chip 300 may also communicate a hidden refresh command one or more of the memory chips 400a-400h via the first bus 230.

The buffer chip 300 may transfer write data (i.e., data to be written to one or more of the memory chips 400a-400h) received from the memory controller 120 via the data bus 210 to the memory chips 400a-400h via the respective second buses 240a-240h. Alternately, the buffer chip 300 may transfer read data (data retrieved from one or more of the memory chips 400a-400h) obtained from one or more of the memory chips 400a-400h via the second buses 240a-240h to the memory controller 120 via the data bus 210.

The buffer chip 300 may additionally include signal reproduction circuitry and/or signal synchronization circuit, although such circuitry is not shown in FIGS. 2A, 2B and 2C since it is deemed conventional in nature. For example, the buffer chip 300 may include a capacitive separator circuit, a voltage conversion circuit, and signal multiplexing/de-multiplexing block(s).

The capacitive separator circuit may provide a point-to-point connection between a transmitter/receiver connected to end portions of the buffer chip 300 and the buses 210 and 220. Data communicated to the buffer chip 300 from the buses 210 and 220 may be transmitted to a data chain type port. The capacitive separator circuit provides the buses 210 and 220 with terminations, and may allow the buses 210 and 220 to operate at a relatively higher frequency due to a restricted impedance discontinuity on the buses 210 and 220. The impedance discontinuity may cause a reflection in a waveform restricting the highest frequency of the buses 210 and 220. According to the low impedance discontinuity of the buses 210 and 220, the frequency of the buses 210 and 220 may be increased to a higher rate. If buffering of the buffer chip 300 includes a high speed interface, the memory chips 400a-400h may not have high logic, and may be fabricated at a lower manufacturing cost.

The voltage conversion block may convert the voltage range for an independent signal input from the buses 210 and 220 to the buffer chip 300. The voltage conversion block may include a voltage raising circuit for converting a voltage range corresponding to the output of the memory controller 120 to a voltage range corresponding to an input to the memory chips 400a-400h. The voltage conversion block may convert a voltage range of an independent signal output from the memory chips 400a-400h. The voltage conversion block may include a voltage lowering circuit for converting a range corresponding to the output of the memory chips 400a-400h to an input to the memory controller 120.

The de-multiplexing circuit of the multiplexing/de-multiplexing block may process an input having “n” components, and de-multiplex the input to generate an output having “m” component, where n is less than m. Therefore, an input bit rate for each line may be reduced at an n/m ratio in order to maintain bandwidth of an input side constant with that at an output side of the de-multiplexing circuit. Accordingly, the buses 210 and 220 having data input lines to the buffer chip 300, which are narrower than those to the memory chips 400a-400h, may be allowed. This approach may reduce the number of pins necessary in the memory module 100.

The multiplexing circuit of the multiplexing/de-multiplexing block processes an input having “m” lines, and multiplexes the input to generate an output having “n” lines. Thus, an input bit rate of the line may be increased by a ratio of m/n in order to maintain the bandwidth at the input side constant with that at the output side of the multiplexing circuit. Accordingly, the number of data line inputs to the buffer chip 300 may be less than that to the memory chips 400a-400h, and thus, the number of necessary pins in the memory module 100 may be reduced.

Write data may be applied to each of the memory chips 400a-400h via its respective second bus 240a-240h from the buffer chip 300, while corresponding C/S signal(s) are applied to the memory chips 400a-400h via the first bus 230. The requirements for S/C signal lines may be different for each memory chip due to differently available elements related to (e.g.,) voltage conversion, multiplexing/de-multiplexing, etc. Therefore, different multiplexing circuit(s), de-multiplexing circuit, and/or voltage conversion circuitry may be used. In certain embodiments, the multiplexing/de-multiplexing functionality, and/or signal separating functionality with respect to data or related C/S signals may not be used.

The above memory module 100 shows bus paths and wires for buffering the command CMD, the address ADDR, and the data DQ transmitted from the memory controller 120 through the buffer chip 300 and providing the command CMD, the address ADDR, and the data DQ to the memory chips 400a-400h. According to an embodiment of the present inventive concept, the data DQ may be provided to the memory chips 400a-400h directly or via data buffers respectively connected to the memory chips 400a-400h from the memory controller 120, rather than the buffer chip 300.

Referring to FIG. 2B, a memory module 100a includes a plurality of memory chips 400a-400h, a command (CMD)/address (ADDR) register chip 300a, and data buffer chips 250a-250h respectively connected to the memory chips 400a-400h. The command/address register chip 300a receives command and address information from the memory controller 120 via the control bus 220, then buffers/re-drives the command and address information. The command and address information (CMD/ADDR) output from the command/address register chip 300a is provided to the memory chips 400a-400h via the commonly-connected first bus 230.

The command/address register chip 300a may issue a hidden refresh command (HREF) controlling the respective refresh operations of the memory chips 400a-400h in response to an external refresh command, namely, a refresh command (REF) or a self-refresh command (SRE) received from the memory controller 120. For example, a hidden refresh command may be provided to the memory chips 400a-400h via the first bus 230 with the bank address.

The data buffer chips 250a-250h are respectively connected between the memory chips 400a-400h and I/O pins provided by the memory module 100a. Each of the data buffer chips 250a-250h is configured to receive and provide write data (DQ) to a corresponding one of the memory chips 400a-400h, as communicated by the memory controller 120 via the data bus 210. In this regard, each of the data buffer chips 250a-250h may be used to buffer received write data, and then transmit the buffered write data to its corresponding one of memory chips 400a-400h. In analogous manner, each of the data buffer chips 250a-250h may be used to receive, buffer and transfer read data retrieved from its corresponding one of the memory chips 400a-400h to the memory controller 120 via the data bus 210.

Referring to FIG. 2C, a memory module 100b includes a plurality of memory chips 400a-400h and the command/address register chip 300a. As before, the command/address register chip 300a receives command and address information (CMD/ADDR) from the memory controller 120 via the control bus 220, then buffers and re-drives the command and address information (CMD/ADDR). The command and address information provided by the command/address register chip 300a may be communicated to the respective memory chips 400a-400h via the first bus 230.

The command/address register chip 300a may also be used to generate and issue a hidden refresh command (HREF) controlling respective refresh operations for the memory chips 400a-400h in response to an external refresh command (e.g., a refresh command REF or self-refresh command SRE) received from the memory controller 120. The hidden refresh command provided to the memory chips 400a-400h via the first bus 230 may in certain embodiments include a bank address.

In the illustrated embodiment of FIG. 2C, each of the memory chips 400a-400h is connected to the memory controller 120 via a corresponding one of a plurality of data buses 210a-210h, whereby each memory chip is directly wired to the memory controller 120 for receipt and transfer of data. Each of the memory chips 400a-400h may receive write data from the memory controller 120 via a corresponding one of the data buses 210a-210h respectively connected to the memory chips 400a-400h, and read data retrieved from each of the memory chips 400a-400h may also be transferred to the memory controller 120 via one of the data buses 210a-210h.

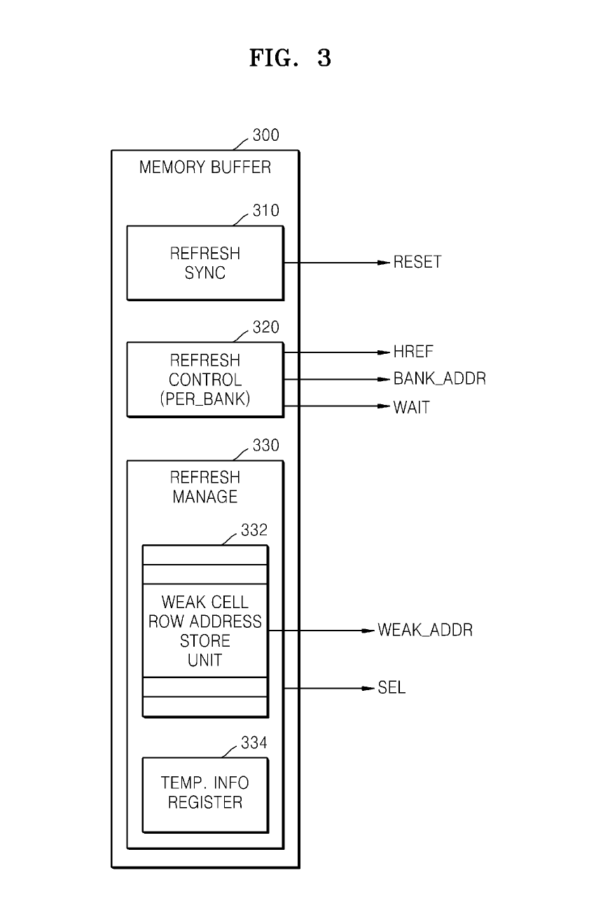

The command/address register chip 300a of FIG. 2C will issue the hidden refresh command controlling the refresh operations of the memory chips 400a-400h similarly to that of the buffer chip 300 that will be described with reference to the embodiment illustrated in FIG. 3. Additionally or alternately, the command/address register chip 300a may be used to refresh banks in the memory chip in a sequential cycling mode, refresh a designated “weak cell row” of the memory chip according to a period shorter than a given refresh period, and/or change the refresh period for the memory chip in accordance with one or more environmental conditions, such as monitored temperature information.

FIG. 3 is a diagram further illustrating in one example a buffer chip 300 according to certain embodiments of the inventive concept.

Referring to FIG. 3, the buffer chip 300 may be used to control the respective refresh operations directed to the memory chips 400a-400h at “a memory module level” (i.e., at a control level not including (or independent of) the memory controller 120 controlling the execution of normal operations by the memory module 100 by a stream of command, address, control signals along with related data signals). Thus, the buffer chip 300 has full control ability and authority to schedule the generation and/or distribution of internal refresh command(s) that will initiate the execution of refresh operations for the memory chips 4001-400h. In this manner, the buffer chip 300 may control the refresh operations of the memory chips 400a-400h without regard to the memory controller 120 or computational components of a larger system using the memory module 100 to store data. As has been suggested above, the internal refresh operations performed by memory chips on the memory module 100 and controlled by the buffer chip 300 may be referred to as “hidden refresh operations”. Accordingly, as shown in FIG. 3, the buffer chip 300 may include a refresh synchronization unit 310, a refresh control unit 320, and a refresh management unit 330 that cooperate to control the identification and execution of hidden refresh operations.

The refresh synchronization unit 310 may be used to generate a reset signal (RESET) that initializes a refresh address generation unit of a memory chip. In effect, the reset signal initializes a refresh counter in the refresh address generation unit.

The refresh control unit 320 may be used to control the refresh operation of a memory cell array of a memory chip according to bank units. That is, the refresh control unit 320 may generate a hidden refresh command (HREF) indicating a hidden refresh operation directed to a particular memory chip and including a bank address (BANK_ADDR). The bank address is provided to select a bank that is currently “idle” (i.e., not busy performing a read/write operation or otherwise in an active mode). Assuming that a memory cell array of the memory chip includes a plurality of banks, the refresh control unit 320 may initiate hidden refresh operations for one or more “idle bank(s)”, while perhaps selectively postponing hidden refresh operations for “active bank(s)”. In this manner, the refresh control unit 320 may effectively schedule hidden refresh operations for all of the banks of a memory chip while minimizing access conflicts with the memory controller 120 that are caused by issuing a wait signal for a period required to refresh all banks of the memory chip.

The refresh control unit 320 may schedule the bank refresh operation in a round-robin approach when performing refresh operations for each bank. According to a round-robin refresh approach, idle banks operations are refreshed as a first (or primary) priority while active banks are thereafter refreshed as they become idle until all banks have been refreshed. The refresh operation of multiple banks using a round-robin approach may be periodically repeatedly, as required.

The refresh control unit 320 may thus control the execution of refresh operations directed to a memory cell array of a memory chip on a bank by bank basis (i.e., on a bank group unit). According to certain embodiments of the inventive concept, a most significant bit (MSB) of the bank address (BANK_ADDR) may be used to classify bank arrays into (e.g.,) upper and lower groups. That is, the full range of bank arrays may be classified into two (2) bank groups. Accordingly, the refresh control unit 320 may generate hidden refresh command(s) in relation to the upper and lower bank groups. Similarly, according to certain embodiments of the inventive concept, the two most significant bits (MSB and MSB−1) of a bank address (BANK_ADDR) may be used to classify an array of banks into four (4) bank groups. Thus, the refresh control unit 320 may generate the hidden refresh command(s) in relation to first, second, third and fourth bank groups.

The refresh control unit 320 may schedule a particular bank group refreshing operation using a round-robin approach when performing the refresh operation for each of a number of designated bank groups. According to a round-robin bank group refresh approach, idle bank groups are primarily refreshed, and the other bank groups are thereafter sequentially refreshed until all of the banks have been refreshed. Here again, a round-robin bank group refreshing operation may be periodically repeatedly.

When performing a hidden refresh operation on a bank bass or a bank group basis, the refresh control unit 320 may communicate information regarding the refresh of a bank or bank group of a memory chip using a pre-charge command to the memory chip in order to reduce the number of total command required to operate the memory chip.

If the refresh control unit 320 receives a command from the memory controller 120 directed to a memory chip currently performing a hidden refresh operation, the refresh control unit 320 may generate the wait signal (WAIT) indicating that the memory chip is currently in a refresh mode. Since the memory chip during a refresh operation may not perform an access operation according to a command received from the memory controller 120, the wait signal will cause the memory controller 120 to reissue the delayed command after execution of the refresh operation and possibly an additional delay period following execution of the refresh operation. Sympathetic with this recognition, the memory controller 120 may be required to issue competent notification to other computational components in the system that execution of the command will be delayed, or requires another request.

The refresh management unit 330 may be used to control a refresh leveraging for the memory chip. The refresh management unit 330 may generate a selection signal (SEL) directing refresh leveraging for a designated weak cell row address (WEAK_ADDR). The selection signal may be set (e.g.,) to a logically “low” level during normal refresh operations, but to a logically “high” level during a refresh leveraging operation.

The refresh management unit 330 may include an address storing unit 332 capable of storing one or more weak cell row address(es) associated with the memory chip. In this regard, the address storing unit 332 may use various kinds of non-volatile memory such as an electric programmable fuse memory, a laser-programmable fuse memory, an anti-fuse memory, a one-time programmable memory, and a flash memory.

According to certain embodiments of the inventive concept, the refresh management unit 330 will not include the address storing unit 332. Rather, as shown in FIG. 6, the address storing unit 332 may be included in a refresh address generation unit of the memory chip. The refresh management unit 330 may be used to store information about a number of weak cell row addresses (WEAK_ADDR) of the memory chip. The refresh management unit 330 may control the refresh operation so that more refresh operations may be performed for as many as the number of weak cell row addresses during the refresh period (tREF), as defined in a specification for the memory chip. For example, assuming information about a number of weak cell row addresses stored in the refresh management unit 330 is 128, and 8K memory cell rows are refreshed for 64 ms according to an applicable specification for a memory chip, then the number of times that a corresponding refresh operations is performed during 64 ms may be assumed to be 8K+128.

The refresh management unit 330 may include a temperature information register 334 capable of storing information obtained from a corresponding (actual or calculated) temperature determination element. One or more relevant temperatures may be monitored, obtained or derived in relation to the entire memory module, the buffer chip 300, and/or the memory chips 400a-400h mounted on the memory module. The temperature information stored in the temperature information register 334 may be used to periodically adjust the refresh time for one or more refresh operations, including hidden refresh operations.

According to certain embodiments of the inventive concept, the refresh management unit 330 will not physically include a temperature sensor. For examples, when one or more temperature determination elements (e.g., sensors) are included in one or more memory chip(s), the refresh management unit 330 need not necessarily have one too.

In such circumstances, the refresh management unit 330 may receive temperature information from (e.g.,) a temperature sensor 425 of FIG. 4 via a signal line connected to a DQ pad of the memory chip, or via a signal line connected to a TI pad of the memory chip. The refresh management unit 330 may receive the temperature information of the temperature sensor 425 as one-bit information via the DQ pad or the TI pad, or may receive and decode the temperature information as serial bit information. The refresh management unit 330 may then be used to determine whether the temperature information transmitted from the memory chip is higher or lower than a reference temperature (TBD).

If it is determined that the temperature information is higher than the reference temperature, the refresh management unit 330 may adjust the refresh period of the memory chip to be shorter than a (default) refresh period (tREF) associated with the reference temperature. Otherwise, if it is determined that the temperature information is lower than the reference temperature, the refresh management unit 330 may adjust the refresh period to be consistent with the (default) refresh period tREF associated with the reference temperature.

As described above, the buffer chip 300 may issue the hidden refresh command that controls execution of refresh operations for the memory chips of a memory module independent of the memory controller 120 normally controlling operation of the memory chips. The buffer chip 300 may be used to generate and provide a wait signal indicating that the memory chip is in the refresh operation in response to the hidden refresh command to the memory controller 120. The buffer chip 300 may refresh a weak cell row of the memory chip according to a refresh period that is shorter than a “normal refresh period” associated with execution of the hidden refresh command. However, the buffer chip 300 may change the normal refresh period associated with the hidden refresh command (HREF) in accordance with temperature information.

FIG. 4 is a diagram of a memory chip 400 capable of executing a hidden refresh operation under the control of the buffer chip 300 according to an embodiment of the inventive concept.

Referring to FIG. 4, the memory chip 400 is assumed to be one of the plurality of memory chips 400a-400h mounted on the memory module 100 of FIG. 1. The memory chip 400 illustrated in relevant portion by FIG. 4 comprises; a control logic unit 410, an address buffer 420, the temperature sensor 425, a bank control logic unit 430, a row address multiplexer 440, a column address latch 450, a row decoder, a memory cell array, a sense amplifier, an input/output (I/O) gating circuit 490, a data input/output buffer 495, and a refresh address generator 500.

The memory cell array may include first to fourth bank memory arrays 480a, 480b, 480c, and 480d. The row decoder may include first to fourth bank row decoders 460a, 460b, 460c, and 460d respectively connected to the first to fourth bank arrays 480a, 480b, 480c, and 480d. The column decoder may include first to fourth bank column decoders 470a, 470b, 470c, and 470d respectively connected to the first to fourth bank arrays 480a, 480b, 480c, and 480d. The sense amplifier may include first to fourth bank sense amplifiers 485a, 485b, 485c, and 485d respectively connected to the first to fourth bank arrays 480a, 480b, 480c, and 480d. The first to fourth bank arrays 480a, 480b, 480c, and 480d, the first to fourth bank row decoders 460a, 460b, 460c, and 460d, the first to fourth bank column decoders 470a, 470b, 470c, and 470d, and the first to fourth bank sense amplifiers 485a, 485b, 485c, and 485d may respectively configure first to fourth banks. In FIG. 4, the memory chip 400 includes four banks; however, the number of banks included in the memory chip 400 is not limited thereto.

Also, according to the present embodiment, the memory chip 400 may be DRAM such as double data rate synchronous dynamic random access memory (DDR SDRAM), low power double data rate (LPDDR) SDRAM, graphics double data rate (GDDR) SDRAM, and Rambus® dynamic random access memory (RDRAM), or a non-volatile memory device that needs to be refreshed.

The control logic 410 may be used to control operations of the memory chip 400. For example, the control logic 410 may generate control signals so that the memory chip 400 may perform a writing operation or a reading operation. The control logic 410 may include a command decoder 411 that decodes the command CMD transmitted from the memory controller 120, and a mode register 412 setting an operation mode of the memory chip 400. For example, the command decoder 411 may decode a writing enable signal (/WE), a row address strobe signal (/RAS), a column address strobe signal (/CAS), and a chip selection signal (/CS) to generate control signals corresponding to the command CMD.

The control logic 410 may further receive a clock CLK and a clock enable signal CKE for driving the memory chip 400 in a synchronization method. The control logic 410 controls the refresh address generator 500 to perform an auto-refresh operation in response to the refresh command REF, or controls the refresh address generator 500 to perform a self-refresh operation in response to the self-refresh enter command SRE. Also, the control logic 410 may control the refresh address generator 500 to perform a hidden refresh operation in response to the hidden refresh command HREF.

The address buffer 420 may receive an address ADDR including a bank address BANK_ADDR, a row address ROW_ADDR, and a column address COL_ADDR from the memory controller 120. Also, the address buffer 420 may provide the bank control logic 430 with the bank address BANK_ADDR, provide the row address multiplexer 440 with the row address ROW_ADDR, and provide the column address latch 450 with the column address COL_ADDR.

The temperature sensor 425 may be used to provide temperature information related to the memory chip 400. For example, the temperature sensor 425 may detect the ambient temperature of the memory chip 400 and provide the resulting temperature information to the buffer chip 300. The temperature information provided by the temperature sensor 425 may be provided to the buffer chip 300 via one of a plurality of signal lines. The memory chip 400 may output the temperature information of the temperature sensor 425 via (e.g.,) a DQ pad. Alternately, the memory chip 400 may include an additional pad for outputting the temperature information provided by the temperature sensor 425. The memory chip 400 may include, for example, a temperature information (TI) pad, and may provide the buffer chip 300 with the temperature information of the temperature sensor 425 via a signal line connected to the TI pad.

If the temperature information is output by a DQ pad or a TI pad, the temperature information may be expressed as a single bit in certain embodiments. If the temperature information of the temperature sensor 425 is higher than the reference temperature (TBD), the DQ pad or TI pad will output (e.g.,) a high, but if the temperature information is lower than the reference temperature, the DQ pad or TI pad will output a low.

In another example, the temperature information provided at the DQ pad or TI pad may be provided in the form of serial bit information. That is, the memory chip 400 may output serial bit information (e.g., 0110010100) to the DQ pad or TI pad in accordance with a clock signal. The serial bit information output via the DQ pad or TI pad may thus be provided to the buffer chip 300.

The bank control logic 430 may be used to generate bank control signals in response to the bank address (BANK_ADDR). In response to the bank control signals, a bank row decoder corresponding to the bank address from among the first to fourth row decoders 460a, 460b, 460c, and 460d is activated, and a bank column decoder corresponding to the bank address from among the first to fourth bank column decoders 470a, 470b, 470c, and 470d may be activated.

The bank control logic 430 may generate bank group control signals in response to the bank address that determines the bank groups. In response to the bank group control signals, row decoders of the bank group corresponding to the bank address from among the first to fourth bank row decoders 460a, 460b, 460c, and 460d are activated, and column decoders of the bank group corresponding to the bank address from among the first to fourth bank column decoders 470a, 470b, 470c, and 470d may be activated.

The row address multiplexer 440 may receive the row address (ROW_ADDR) from the address buffer 420, and may receive a refresh row address (REF_ADDR) from the refresh address generator 500. The row address multiplexer 440 may selectively output the row address or the refresh row address. The row address output from the row address multiplexer 440 may be applied respectively to the first to fourth bank row decoders 460a, 460b, 460c, and 460d.

The bank row decoder activated by the bank control logic 430 from among the first to fourth bank row decoders 460a, 460b, 460c, and 460d decodes the row address output from the row address multiplexer 440 so as to activate a word line corresponding to the row address. For example, the activated bank row decoder may apply a word line driving voltage to the word line corresponding to the row address.

The column address latch 450 receives a column address (COL_ADDR) from the address buffer 420, and temporarily stores the column address. The column address latch 450 may gradually increase the column address in a burst mode. The column address latch 450 may apply the column address that is temporarily stored or gradually increased respectively to the first to fourth bank column decoders 470a, 470b, 470c, and 470d.

The bank column decoder activated by the bank control logic 430 from among the first to fourth bank column decoders 470a, 470b, 470c, and 470d may activate a sense amplifier corresponding to the bank address and the column address via the input/output gating circuit 490.

The input/output gating circuit 490 may include an input data mask logic, read data latches for storing data output from the first to fourth bank arrays 480a, 480b, 480c, and 480d, and a writing driver for writing data to the first to fourth bank arrays 480a, 480b, 480c, and 480d, with circuits gating the input/output data.

Data read from one of the first to fourth bank arrays 480a, 480b, 480c, and 480d may be sensed and amplified by the sense amplifier, and may be stored in the read data latches. The read data stored in the read data latch may be provided to the memory controller 120 via the data input/output buffer 495. Write data to be written in one of the first to fourth bank arrays 480a, 480b, 480c, and 480d may be provided to the data input/output buffer 495 from the memory controller 120. Data provided to the data input/output buffer 495 may be written in one bank array via the writing driver.

The refresh address generator 500 may generate the refresh row address (REF_ADDR) corresponding to the memory cell row that will be refreshed. The refresh operation may include a normal refresh operation for refreshing each of the memory cell rows sequentially and a refresh leveraging operation for refreshing weak cell rows. The normal refresh operation may be referred to as a CAS-before-RAS or CBR refresh operation. The CBR refresh is a scheme that generates a refresh row address by a counter in the memory chip 400 whenever there is a refresh request, without an external input of a row address.

The refresh address generator 500 may generate the refresh row address in response to a reset signal and a selection signal provided from the buffer chip 300. The refresh address generator 500 includes a refresh counter generating a CBR refresh row address through a counting operation, and may initialize the refresh counter in response to the selection signal. The refresh address generator 500 may select the CBR refresh row address or the weak cell row address provided from the buffer chip 300 in response to the selection signal, and may output the selected signal as the refresh row address.

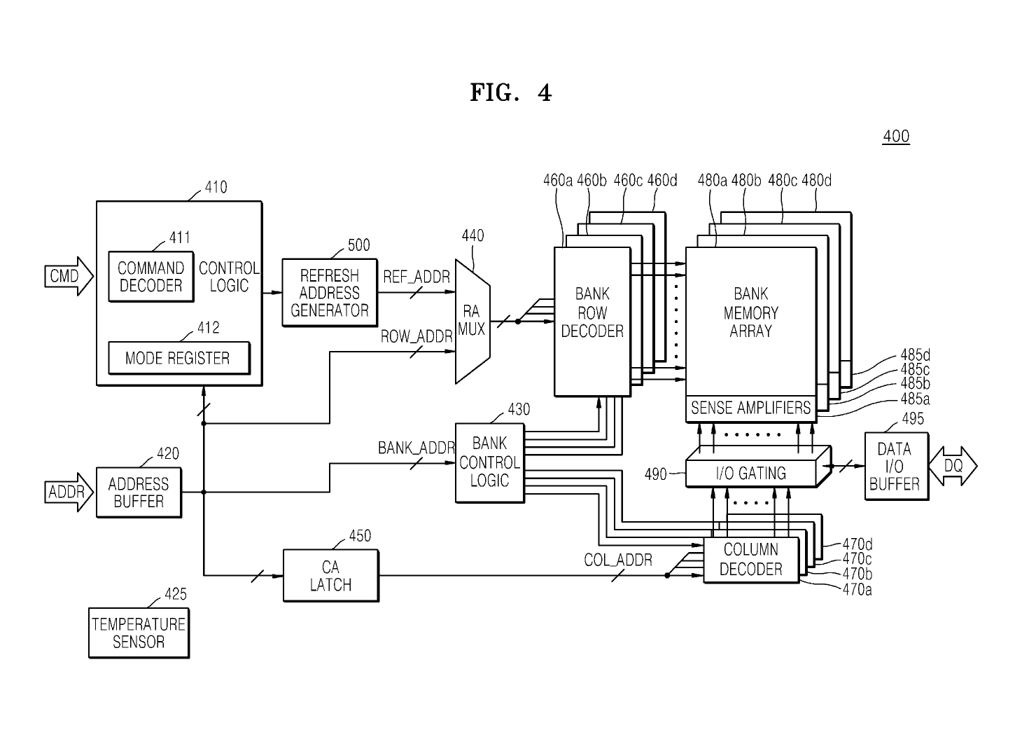

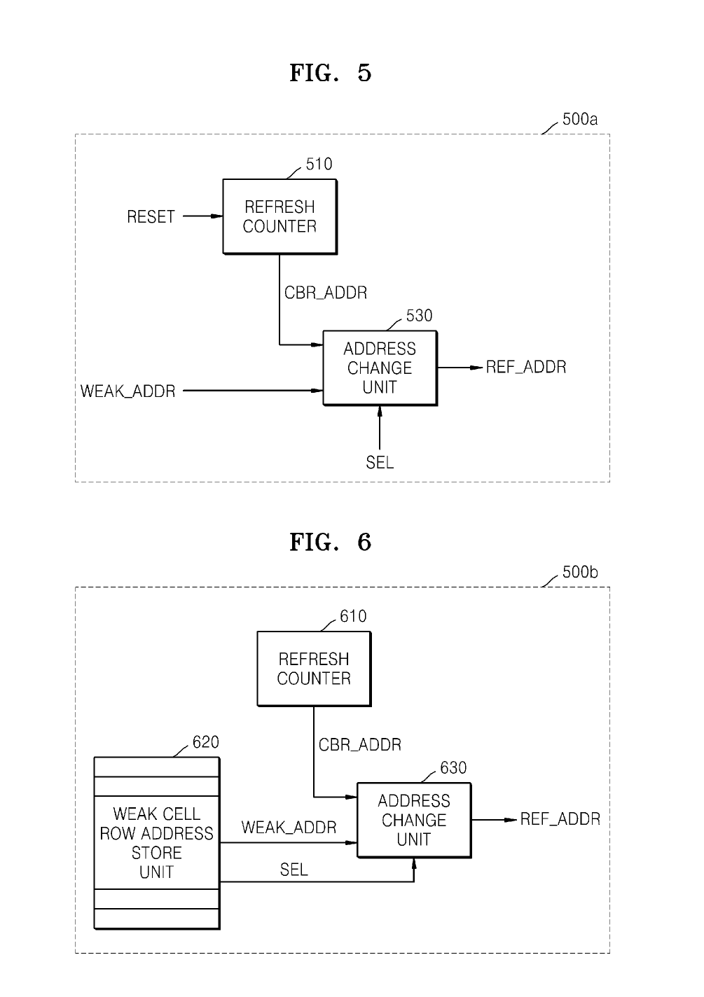

FIG. 5 is a block diagram further illustrating in one example the refresh address generator 500 of FIG. 4.

Referring to FIG. 5, a refresh address generator 500a may be used to generate the refresh row address (REF_ADDR) in response to the reset signal (RESET), a selection signal (SEL), and a weak cell row address (WEAK_ADDR) provided by the buffer chip 300. The refresh address generator 500a may include a refresh counter 510 and an address change unit 530.

The refresh counter 510 performs a counting operation in a normal refresh operation to generate a CBR refresh row address (CBR_ADDR). The refresh counter 510 is initialized by the reset signal, and resets the CBR refresh row address to 0. The reset signal may be provided from the refresh synchronization unit 310 of the buffer chip 300.

The refresh counter 510 gradually increases the CBR refresh row address. When the CBR refresh row address exceeds a maximum row address, the refresh counter 510 may initialize the CBR refresh row address a minimum row address, that is, as a 0.

The address change unit 530 receives the CBR refresh row address and the weak cell row address, and generates the refresh row address in response to the selection signal. Hence, the refresh row address denotes a memory cell row to be refreshed. The weak cell row address and the selection signal may be provided from the refresh management unit 330 of the buffer chip 300. The weak cell row address may be provided from the address storing unit 332 in the refresh management unit 330.

The address change unit 530 may generate the CBR refresh row address (CREF_ADDR) as the refresh row address (REF_ADDR) when the selection signal (SEL) is low. Alternately, the address change unit 530 may generate the weak cell row address (WEAK_ADDR) as the refresh row address (REF_ADDR) when the selection signal (SEL) is high.

As described above, the refresh address generator 500a allows the CBR refresh row address provided from the refresh counter 510 to be refreshed during the normal refresh operation, and allows the weak cell row address provided from the address storing unit 332 of the buffer chip 300 to be refreshed during the refresh leveraging operation.

FIG. 6 is a block diagram further illustrating in another example the refresh address generator 500 of FIG. 4.

Referring to FIG. 6, a refresh address generator 500b is different from the refresh address generator 500a of FIG. 5 by the further inclusion of an address storing unit 620. The refresh address generator 500b may be used to generate the refresh row address (REF_ADDR) in connection with information about the number of weak cell row addresses (WEAK_ADDR) stored in the buffer chip 300. The refresh address generator 500b may generate the selection signal (SEL) internally at every refresh leverage cycle that is determined according to the information about the number of weak cell row addresses in the buffer chip and the weak cell address stored in the address storing unit 620. The refresh address generator 500b may include a refresh counter 610, the address storing unit 620, and an address change unit 630.

The refresh counter 610 performs a counting operation in a normal refresh operation to generate the CBR refresh row address (CBR_ADDR). The refresh counter 610 is initialized by the reset signal (RESET), and may reset the CBR refresh row address to 0. The reset signal may be provided from the refresh synchronization unit 310 of the buffer chip 300. The refresh counter 610 gradually increases the CBR refresh row address, and when the CBR refresh row address becomes greater than the maximum row address, the CBR refresh row address may be initialized as the minimum row address, that is, 0.

According to the embodiment of the present inventive concept, the refresh counter 610 may output an arbitrary CBR refresh row address according to the counting operation. The refresh counter 610 gradually increases the CBR refresh row address, and when the CBR refresh row address becomes greater than the maximum row address, the CBR refresh row address is initialized as the minimum row address, that is, 0. After that, the refresh counter 610 may generate the CBR refresh row address that is gradually increased from the minimum row address 0.

As noted above, the address storing unit 620 may be used to store at least one weak cell row address. The address storing unit 620 may generate the selection signal for refreshing the weak cell address according to an appropriate order of the refresh command in communication with the refresh counter 610. The number of weak cell row addresses stored in the address storing unit 620 may correspond to the number of weak cell rows included in the first to fourth bank memory arrays 480a-480d in the memory chip 400. (See, e.g., FIG. 4). The weak cell row addresses stored in the address storing unit 620 may be sequentially refreshed at the timings of the refresh leveraging operations in the refresh operation.

The weak cell row addresses may be stored in the address storing unit 620 before packaging the memory chip 400 (see FIG. 4). Also, the weak cell row addresses may be stored in the address storing unit 620 after packaging the memory chip 400. The address storing unit 620 may be various kinds of non-volatile memory devices such as an electric programmable fuse memory, a laser-programmable fuse memory, an anti-fuse memory, a one-time programmable memory, and a flash memory.

The address change unit 630 receives the CBR row address and the weak cell row addresses, and may generate the refresh address in response to the selection signal. The address change unit 630 may generate the CBR refresh row address as the refresh address when the selection signal is low. Alternately, the address change unit 630 may generate the weak cell row address as the refresh address when the selection signal is high.

As described above, the refresh address generator 500b according to certain embodiments of the inventive concept may allow the CBR refresh row address (CREF_ADDR) provided from the refresh counter 610 to be refreshed during normal refresh operations, and may allow the weak cell row address (WEAK_ADDR) provided from the address storing unit 620 of the memory chip 400 to be refreshed during refresh leveraging operations.

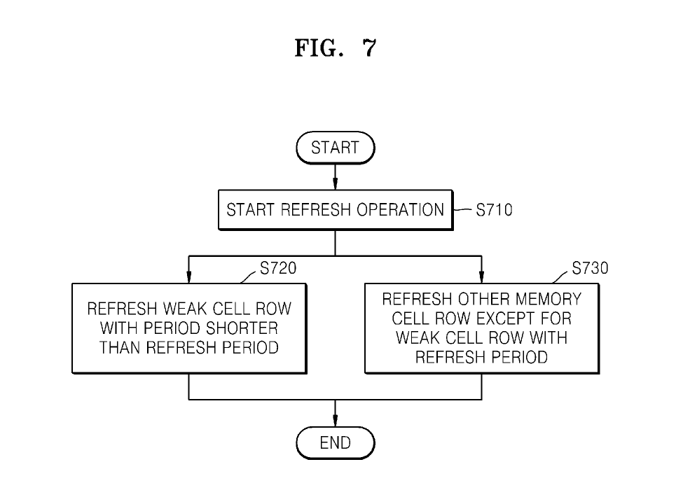

FIG. 7 is a flowchart summarizing a method of refreshing a memory chip including a buffer chip according to certain embodiments of the inventive concept.

Referring to FIG. 7, when the memory chip is turned ON, a refresh operation starts (S710). For example, upon finishing a power-up sequence or a power-down sequence, a designated refresh operation is started. In certain embodiments, the designated refresh operation is an auto-refresh operation in which the refresh row addresses are generated in response to a refresh command (REF) periodically applied, whereby a memory cell row corresponding to the refresh row address is refreshed. In certain other embodiments, the designated refresh operation is a self-refresh operation in which a self-refresh mode starts in response to a self-refresh enter command (SRE) and memory cell rows are periodically refreshed using a built-in timer running during the self-refresh mode. In still other embodiments, the designated refresh operation is a hidden refresh operation in which a refresh row address is generated in response to the hidden refresh command (HREF) and a memory cell row corresponding to the refresh row address is refreshed.

However defined, when the designated refresh operation starts, at least one weak cell row will be refreshed in accordance with a refresh period that is shorter than a normal refresh period (tREF) (S720) in a refresh leveraging operation adapted to the weak cells. Simultaneously with the refresh leveraging operation, normal memory cell rows (excepting the weak memory cell rows) are refreshed using the normal refresh period (tREF) (S730). Consistent with this normal refresh operation, the normal memory cell rows indicated by the CBR refresh row address (CBR_ADDR), as gradually increased by the refresh counter, are refreshed.

In addition, during the continuously performed normal refresh operation, the CBR refresh row address (CREF_ADDR) will coincide with the weak cell row. Here, the corresponding weak cell row may be refreshed once more during the normal refresh operation mode. For example, a refresh leverage cycle of 16 ms may be set to be performed four (4×) times during a refresh period tREF of 64 ms. In this case, the weak cell row may be refreshed twice with a period that is shorter than the refresh leverage cycle of 16 ms.

As described above, the weak cells having a relatively shorter data retention capability are refreshed according to a period that is shorter than the normal refresh period tREF, as will typically be defined according to the specification associated with the memory chip. In this context, memory cells of a weak cell row need not necessarily be replaced by memory cells provide by a redundancy cell row. Accordingly, overall size of a redundancy memory cell array as well as corresponding redundancy circuit for the memory chip may be reduced.

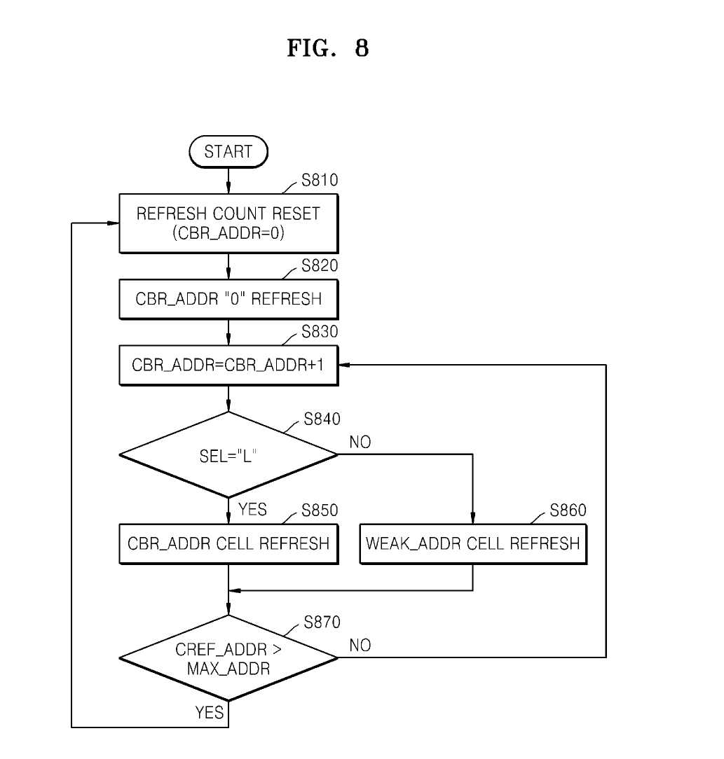

FIG. 8 is a flowchart summarizing a method of refreshing a memory chip, according to certain other embodiments of the inventive concept. FIG. 8 will be described with reference to the refresh address generation units 500a and 500b shown in FIGS. 5 and 6.

Referring to FIG. 8, when the refresh operation starts, the refresh counter 510 or 610 may be initialized (S810). The refresh counter 510 or 610 may reset the CBR refresh row address (CBR_ADDR) to 0 in response to the reset signal (RESET) provided by the refresh synchronization unit 310 of the buffer chip 300. A memory cell row corresponding to the CBR refresh row address of 0 is refreshed (S820). The refresh counter 510 or 610 may generate the CBR refresh row address increased by 1 (S830).

If the selection signal (SEL) provided from the refresh management unit 330 of the buffer chip 300 is low (“L”) (S840=Yes), the memory cell row corresponding to the CBR refresh row address will be refreshed (S850). Otherwise, if the selection signal is high (S840=No), the weak cell row corresponding to the weak cell row address (WEAK_ADDR) will be refreshed (S860).

If the CBR refresh row address is not greater than a maximum row address (MAX_ADDR) among the row addresses of the memory cell rows included in the memory cell array (S870=No), the refresh counter 510 or 610 generates a CBR refresh row address that is increased by one (S830), and the CBR refresh operation including operations S840 and S850 are repeated.

However, if the CBR refresh row address is greater than the maximum row address (S870=Yes), the CBR refresh row address is re-initialized (S810). Since the CBR refresh row address is initialized, the memory cell rows included in the memory cell array will again be sequentially refreshed.

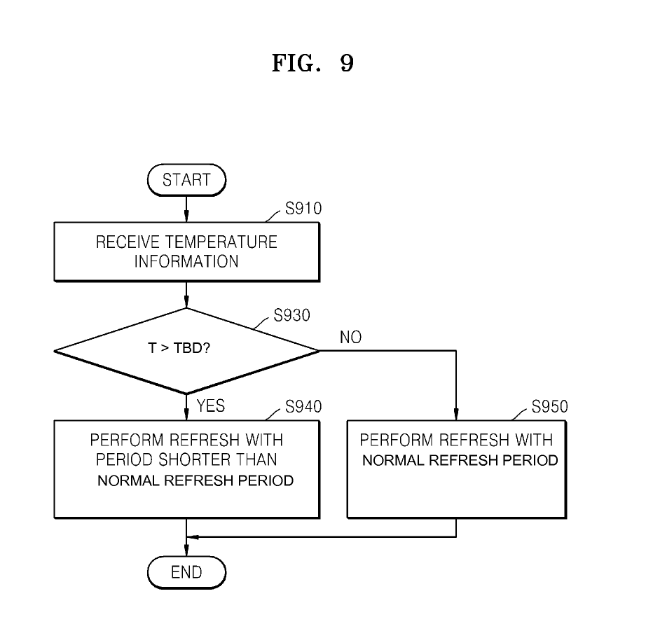

FIG. 9 is a flowchart summarizing a method of refreshing a memory chip having a buffer chip according to another embodiment of the inventive concept. FIG. 9 illustrates a refresh method for a case wherein a temperature sensor is used to monitor an operating temperature related to the memory module, the resulting temperature information being stored in a temperature information register provided by the buffer chip. The temperature monitoring period may be adjusted to a predetermined period set in the temperature information register.

Referring to FIG. 9, the buffer chip receives temperature information from the temperature sensor (S910). If the buffer chip determines that temperature information (T) from the temperature sensor is not greater than a reference temperature (TBD) (S930=No), then the refresh period for a refresh operation performed by the memory chip will be set to a normal refresh period (tREF) (i.e., one established by a manufacturers specification for the constituent memory chip in view of the reference temperature) (S950). Otherwise, so long as the temperature information (T) indicates that the operating temperature remains lower than the reference temperature (TBD) (S930=Yes), the buffer chip sets the refresh period for the refresh operation performed by the memory chip to be relatively shorter than the normal reference period (tREF) (S940).

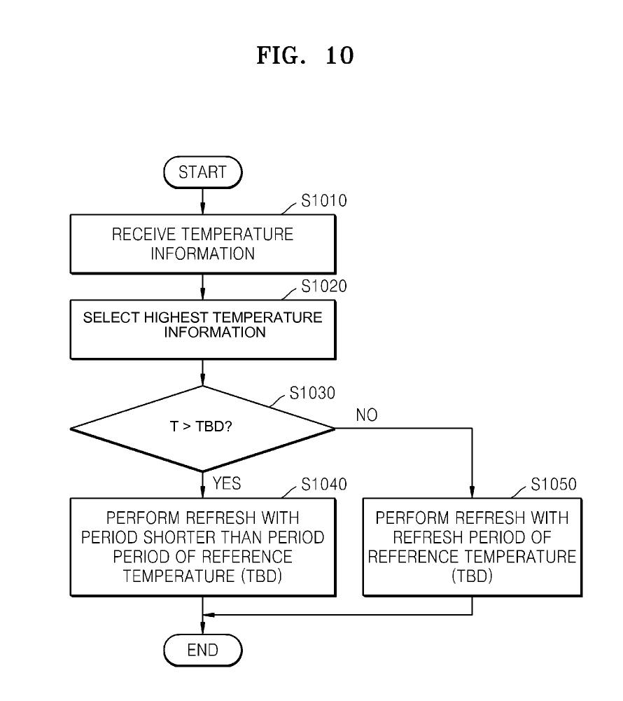

FIG. 10 is a flowchart summarizing a method of refreshing a memory chip having a buffer chip according to another embodiment of the present inventive concept. FIG. 10 illustrates another refresh method assuming a case where temperature sensor(s) provide appropriate temperature information related to a memory module and/or one of its constituent components.

Referring to FIG. 10, the buffer chip receives and stores temperature information from the temperature sensor(s) (S1010). The buffer chip then selects temperature information (T) indicating a highest temperature (S1020). If the buffer chip determines that the selected temperature information (T) is higher than a reference temperature (TBD) (S1030=Yes), then the buffer chip sets the refresh period for memory chips mounted on the memory module to be shorter than a normal refresh period (tREF) (S1040). Otherwise, if the buffer chip determines that the selected temperature information (T) is lower than the reference temperature (TBD) (S1030=No), the buffer chip sets the refresh period of the memory chips to be the normal refresh period tREF (S1050).

The refresh method of FIG. 10 selects the temperature information indicating a highest temperature from among a number of temperatures indicated by the temperature information. Unlike the above method, the buffer chip may receive the temperature information from the temperature sensor from each of the memory chips, and may change the refresh period of the corresponding memory chip according to the temperature information. When it is determined that the temperature information of the memory chip is higher than the reference temperature, the buffer chip sets the refresh period of the corresponding memory chip to be shorter than the refresh period tREF at the reference temperature. In addition, when it is determined that the temperature information of the memory chip is lower than the reference temperature, the buffer chip may set the refresh period of the corresponding memory chip to be the same as the reference period at the reference temperature.

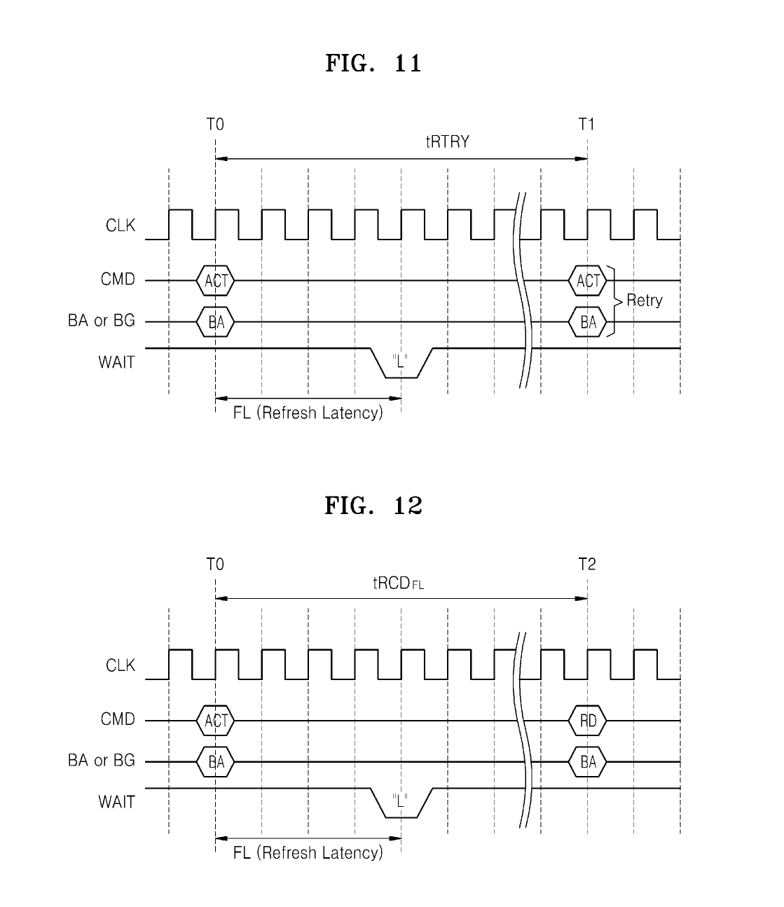

FIGS. 11, 12, 13 and 14 are respective timing diagrams illustrating certain refresh methods for memory chips mounted on a memory module having a buffer chip according to embodiments of the inventive concept.

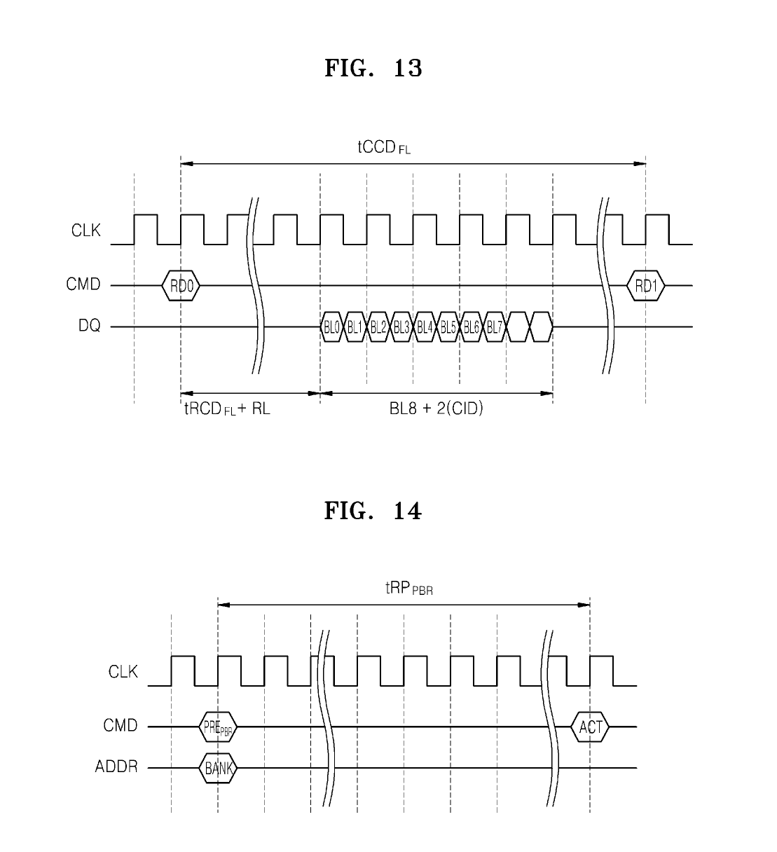

Referring collectively to FIGS. 11, 12, 13, and 14, operational timing between the buffer chip and a memory controller executing a hidden refresh operation is shown. FIGS. 11 and 12 illustrate a case where a wait signal (WAIT) communicated by the buffer chip is allocated to a new pin on the memory module. FIG. 13 illustrates a case where the wait signal is allocated to an existing data I/O pin (i.e., a DQ pin).

Referring to FIG. 11, it is assumed that during the hidden refresh operation, the memory controller issues an active command (ACT) at time T0. The memory controller is further assumed to provide a bank address signal (BA) or bank group signal (BG) in conjunction with the active command.

The buffer chip receives the active command and the bank address or bank group signal BA/BG in synchronization with the clock (CLK), and generates a low wait signal following a first predetermined delay (FL). Here, the first predetermined delay may be defined as a time corresponding to a refresh latency. The refresh latency may be set according to a number of clock cycles (e.g., 4 clock cycles).

The wait signal is transmitted to the memory controller. Hence, the memory controller may ignore the active command issued at a time T0 in response to the wait signal. But the memory controller reissues the active command (ACT) at time T1 after a second predetermined delay (tRTRY) following time T0. Here again, the memory controller may output the bank address or bank group signal with the active command ACT at the time T1.

In the illustrated example of FIG. 11, the second predetermined delay (tRTRY) may be set to be equal to a normal refresh time (tRFC) during which a memory cell may typically be refreshed. Thus, the refresh time (tRFC) may vary in accordance with the data storage capacity of a DRAM, for example. Accordingly, a minimum second predetermined time (tRTRYmin) may be set as a minimum refresh time (tRFCmin).

In the timing diagram of the refresh operation illustrated by FIG. 11, when the buffer chip receives the active command from the memory controller during the refresh operation, the buffer chip will generate the wait signal following a defined refresh latency period. The memory controller upon receiving the wait signal will ignore the first active command that provoked the wait signal, and will subsequently reissue a second (and same) active command (ACT) following a refresh time tRFC.

Referring to FIG. 12, during the hidden refresh operation executed in relation to one or more memory chips of a memory module having a buffer chip, the memory controller is assumed to issue an active command (ACT) at a time T0. As before, the memory controller may output the bank address signal BA or bank group signal BG in conjunction with the active command.

The buffer chip receives the active command and the bank address signal BA synchronously with the clock (CLK), and generate a low wait signal (WAIT) after a refresh latency period (FL). Thereafter, the memory controller issues a read command (RD) (or alternately a write command (WR)) associated with the active command and a corresponding bank address signal or bank group signal at a time T2 after a third delay (tRCDFL) from the time T0 and in response to the wait signal.

Here, the third delay (tRCDFL) may be set as a time obtained by adding the refresh time tRFC taken to refresh one memory cell to a /RAS to /CAS delay time tRCD (tRFC+tRCD). The /RAS to /CAS delay time tRCD is a time period between application of a /RAS signal and application of a /CAS signal, and the refresh time tRFC may increase according to the capacity of a DRAM memory. Accordingly, a minimum of the third predetermined time tRCDFLmin may be set as a sum of the minimum refresh time and the minimum /RAS to /CAS delay time (tFRCmin+tRCDmin).

In the timing diagram of the refresh operation of FIG. 12, when the buffer chip receives the active command from the memory controller during the refresh operation of the memory chip, the buffer chip may generate a wait signal after the refresh latency. The memory controller receiving the wait signal may issue a read or write command RD or WR relating to the active command after delaying for a sum of the refresh time tRFC and the /RAS to /CAS delay time tRCD (tRFC+tRCD=tRCDFL) from the active command ACT issued before receiving the wait signal.

Referring to FIG. 13, during a hidden refresh operation executed in relation to memory chips of a memory module having a buffer chip, a command identification signal (CID) indicating that the command transmitted from the memory controller will be delayed due to execution of the refresh operations by the memory chips is communicated to the memory controller via an existing data I/O pin (e.g., a DQ pin). The buffer chip may output the command identification signal CID via the DQ pin in order to provide notification that the memory controller command will be delayed in its execution. Thus, in certain embodiments of the inventive concept, the command identification signal CID functions as a wait signal of sorts (e.g., see FIGS. 11 and 12) indicating the ongoing execution of a refresh operation by one or more memory chips on a memory module operation in relation to one or more commands communicated from a memory controller operationally associated with the memory chips.

Thus, in the illustrated example of FIG. 13, the buffer chip is assumed to receive a first read command (RD0) issued by the memory controller synchronously with a clock signal (CLK). In response, the memory chips provide the requested read data in a format defined by a given burst length (BL) to one or more data I/O pin(s) (e.g., a DQ pin). Here, the read data (BL0-BL7) is assumed to have a burst length of BL=8, and the read data is applied to a DQ pin on rising and falling edges of the clock.

Under these assumptions, the buffer chip may output a command identification signal (CID) related to the first read command that indicates that the requested read data (BL0-BL7) may be delayed in its presentation at the DQ pin. That is, the command identification signal (CID) will be communicated following the read data, and is assumed to include 2 serially communicated bits.

Of course, the command identification signal may take many different forms and the serial 2-bit format is merely one selected example. For example, the command identification signal (CID) may include parallel bits provided to two or more DQ pins.

Thus, in a case where the first read command RD0 is communicated from the memory controller to the buffer chip during ingoing refresh operation(s) for the memory chips, the buffer chip may response by communicating the command identification signal (CID) following output of the read data (BL)-BL7) via the DQ pin.

Hence, a first bit of the provided read data (BL0) provided to the DQ pin may be read after a delay period equaling a sum of time tRCDFL and a read latency RL (tRCDFL+RL), where tRCDFL is a sum of the refresh time tRFC taken to refresh one memory cell and the /RAS to /CAS delay time tRCD (tRFC+tRCD=tRCFDL), as described with reference to FIG. 12.

The memory controller may issue a second read command (RD1) after a predetermined time tCCDFL following issuing the first read controller RD0. The predetermined time tCCDFL may be set as a time including the time tCCD to which a delay according to the refresh operation of the memory chip is applied. The time tCCD is a time period between a /CAS signal and a next /CAS signal. A minimum predetermined time tCCDFLmin may be set as a time obtained by adding the time required to output the read data having a burst length of (e.g.,) BL=8 and the time required to output the command identification signal. In the illustrated example of FIG. 13, the minimum predetermined time tCCDFLmin may be set as 5 clock cycles including 4 clock cycles for output of the read data and one clock cycle for output of the command identification signal.

During the refresh method shown in FIG. 13, the buffer chip may output the command identification signal indicating that a read command communicated from the memory controller may be delayed due to a refresh operation being executed by one or more of the memory chips. And as noted above, this command identification signal may be provided to the memory controller after the read data requested by the read command has been output via one or more DQ pin(s).

Referring to FIG. 14, the buffer chip may schedule refresh operations for a particular bank, bank group, or sequence of banks/bank groups during a hidden refresh operation executed by the memory chips. Thus, the buffer chip may transfer the refresh commands for each bank/bank group chips together with precharge commands to the memory chips. This type of precharge command may be referred to as a combined precharge command (PRE_{PBR}).

In the illustrated example of FIG. 14, the combined precharge command is synchronously provided with the clock, and may be transferred to the memory chips together with the corresponding bank addresses (BANK) for banks to be refreshed. In one example, the bank address has a (e.g.,) 5 bit format, including 4 address bits identifying the bank to be refreshed and 1 refresh information bit indicating whether or not the identified bank will be refreshed.

After issuing the combined precharge command (PRE_{PBR}), a time (tRP_{PBR}) for pre-charging a bit line is necessary for preparing for a next active command (ACT). The time tRP_{PBR} may be referred to as a combined row precharge time. The combined row precharge time tRP_{PBR} may be set as a sum of the row precharge time tRP and the refresh time tRFC for refreshing one memory cell (tRP+tRFC).

It is possible that the buffer chip may not load the refresh commands for each bank in the precharge command. In this case, a time from the issuing of the precharge command PRE to the next active command ACT may be set as a precharge time tRP.

Thus, in the refresh method of FIG. 14, the buffer chip may communicate information regarding the refresh of particular banks of the memory chips and this information may be communicated with the precharge command to the memory chips. Accordingly, the precharge command and the refresh command for each bank may be merged, thereby reducing the number of overall commands that must be exchanged between the memory controller and buffer chip and ensuring a given command bandwidth.

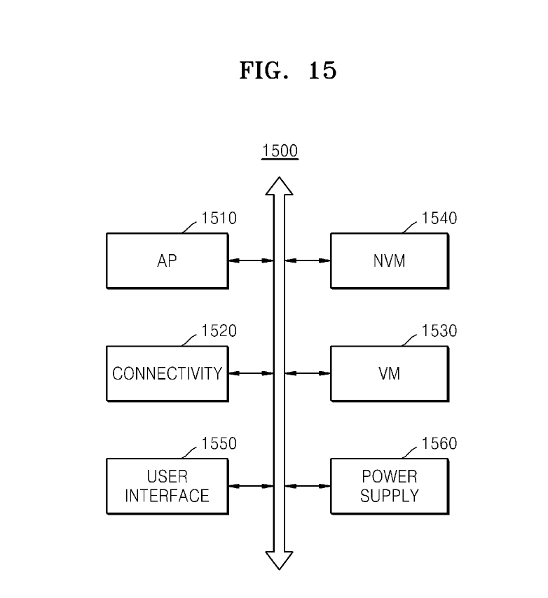

FIG. 15 is a block diagram illustrating a mobile system 1500 that may incorporate a memory module having buffer chip and memory chips according to an embodiment of the inventive concept.

Referring to FIG. 15, the mobile system 1500 comprises in relevant portion an application processor 1510, a connectivity unit 1520, a volatile memory device 1530, a user interface 1550, and a power supply 1560. In various configurations the mobile system 1500 may be a mobile phone, smart phone, personal digital assistant (PDA), portable multimedia player (PMP), digital camera, digital music player, portable game console, navigation system, etc.

The application processor 1510 may execute applications providing an Internet browser, games, and moving pictures. According to the present embodiment, the application processor 1510 may include a processor core (single core) or a plurality of processor cores (multi-core). For example, the application processor 1510 may include a dual-core, a quad-core, or a hexa-core. Also, the application processor 1510 may further include a cache memory located in or outside the application processor 1510.

The connectivity unit 1520 may communicate with an external device wirelessly or through a wire. For example, the connectivity unit 1520 may perform Ethernet communication, near field communication (NFC), radio frequency identification (RFID) communication, mobile telecommunication, memory card communication, or universal serial bus (USB) communication. For example, the connectivity unit 1520 may include a base band chipset, and may support communication such as GSM, GRPS, WCDMA, and HSxPA.

The volatile memory device 1530 may store data processed by the application processor 1510, or may be used as a working (scratch-pad) memory. The volatile memory device 1530 may include one or more memory chip(s) and a buffer chip operatively connected to the memory chip(s), where each memory chip may be DRAM, such as a DDR SDRAM, LPDDR SDRAM, GDDR SDRAM, or RDRAM, or any other volatile memory chip having memory cells that require periodic refresh. In this configuration, the buffer chip may issue a hidden refresh command controlling execution of refresh operation(s) by the memory chip(s), and as described in various approaches above, the buffer chip(s) may output a wait signal indicating ongoing execution of the hidden refresh operation by the memory chip(s). For example, particular banks or bank groups of the memory chip(s) may be refreshed using a round-robin approach, certain weak cell row(s) of the memory chip(s) may be refreshed according to a shorter than normal refresh period, and/or certain refresh period(s) (e.g., the normal refresh period) used to refresh the memory chip(s) may be adjusted in relation to temperature information.

A non-volatile memory device 1540 may be used to store a boot image for booting the mobile system 1500. For example, the non-volatile memory device 1540 may be an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like.

The user interface 1550 may include one or more input devices such as a keypad and a touch screen, and/or a speaker, a display device, and one or more output devices. The power supply 1560 may supply an operating voltage. Also, according to the present embodiment, the mobile system 1500 may include a camera image processor (CIP), and may further include a storage device such as a memory card, a solid state drive (SSD), a hard disk drive (HDD), and a CD-ROM.

The mobile system 1500 or components of the mobile system 1500 may be mounted in various types of packages, for example, package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat-pack (TQFP), small outline integrated circuit (SOIC), shrink small outline package (SSOP), thin small outline package (TSOP), thin quad flat-pack (TQFP), system in package (SIP), multi chip package (MCP), water-level fabricated package (WFP), and water-level processed stack package (WSP).

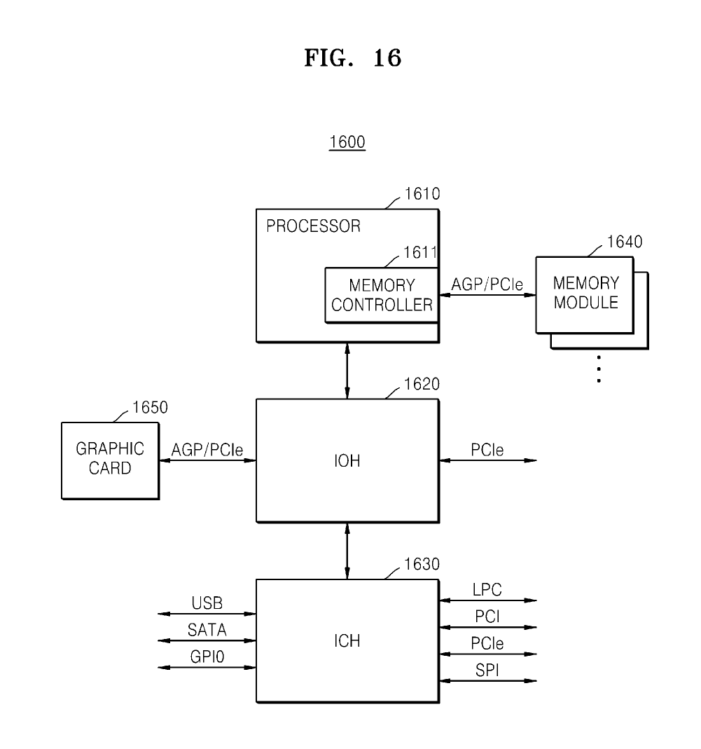

FIG. 16 is a block diagram illustrating a computer system 1600 that may incorporate one or more memory module(s) including memory chip(s) and a buffer chip according to certain embodiments of the inventive concept.

Referring to FIG. 16, the computer system 1600 comprises in relevant portion a processor 1610, an input/output (I/O) hub (IOH) 1620, a I/O controller hub (ICH) 1630, at least one memory module 1640, and a graphic card 1650. In various configurations, the computer system 1600 may be a personal computer (PC), server, workstation, laptop computer, mobile phone, smartphone, PDA, PMP, digital camera, digital TV, set-top box, music player, portable game console, navigation system, etc.

The processor 1610 may execute various computing functions such as certain calculations or tasks. For example, the processor 1610 may be a micro-processor or a CPU. According to the present embodiment, the processor 1610 may include a single core or a plurality of processor cores (multi-core). For example, the processor 1610 may include a dual-core, a quad-core, or a hexa-core. Also, although the computer system 1600 of FIG. 16 includes one processor 1610; however, the computer system 1600 may include a plurality of processors, according to the embodiments of the present inventive concept. Also, the processor 1610 may further include a cache memory located inside or outside thereof.

The processor 1610 may include a memory controller 1611 controlling operations of the memory module 1640. The memory controller 1611 included in the processor 1610 may be referred to as an integrated memory controller (IMC). A memory interface between the memory controller 1611 and the memory module 1640 may include one channel including a plurality of signal lines, or a plurality of channels. Also, one or more memory modules 1640 may be connected to each of the channels. According to the present embodiment, the memory controller 1611 may be located in the input/output hub 1620. The input/output hub 1620 including the memory controller 1611 may be referred to as a memory controller hub (MCH).

The memory module 1640 may include a plurality of memory chips storing data provided from the memory controller 1611 and a buffer chip. As above, the memory chips may be DRAMS such as DDR SDRAM, LPDDR SDRAM, GDDR SDRAM, or RDRAM, or any other volatile memory chip having memory cell that require period refresh. The buffer chip may be used to issue a hidden refresh command controlling refresh operations for the memory chips as variously described above.

The I/O hub 1620 may be used to manage data communications between various devices such as the graphic card 1650 and processor 1610. The I/O hub 1620 may be connected to the processor 1610 via various kinds of interfaces. For example, the I/O hub 1620 and processor 1610 may be connected via various interfaces such as a front side bus (FSB), a system bus, a hyper-transport, a lighting data transport (LDT), quick-path interconnect (QPI), a common system interface, or a peripheral component interface-express (CSI). In FIG. 16, the computer system 1600 is shown as including only one I/O hub 1620, but a plurality of I/O hubs might alternately be used.

The I/O hub 1620 may be used to provide various interfaces to the illustrated components and similar devices. For example, the I/O hub 1620 may be used to implement an accelerated graphics port (AGP) interface, a peripheral component interface-expression (PCIe), and a communications streaming architecture (CSA) interface.

The graphic card 1650 may be connected to the I/O hub 1620 via the AGP or the PCIe. The graphic card 1650 may control a display device (not shown) for displaying images. The graphic card 1650 may include an internal processor for processing image data, and an internal semiconductor memory. According to the illustrated example of FIG. 16, the I/O hub 1620 is connected to a graphics device via the graphic card 1650 disposed external to the I/O hub 1620. However, in other embodiments an integrated graphics approach might be used. For example, the I/O hub 1620 including the memory controller and graphic device may be referred to as a graphic and memory controller hub (GMCH).

The I/O controller hub 1630 may be used to perform data buffering and interface relay so that various system interfaces operate effectively. The I/O controller hub 1630 may be connected to the I/O hub 1620 via an internal bus. For example, the I/O hub 1620 and the I/O controller hub 1630 may be connected via a direct media interface (DMI), a hub interface, an enterprise south-bridge interface (ESI), or PCIe.

The I/O controller hub 1640 may be used to provide various interfaces with peripheral devices. For example, the I/O controller hub 1630 may provide a universal serial bus (USB) port, a serial advanced technology attachment (SATA) port, a general purpose input/output (GPIO), a low pin count (LPC) bus, a serial peripheral interface (SPI), PCI, or PCIe.

Those skilled in the art will recognize that two or more of the foregoing components (e.g., processor 1610, I/O hub 1620, and I/O controller hub 1630) might be physically realized in a single chipset.

While the inventive concept has been particularly shown and described with reference to exemplary embodiments thereof, it will be understood that various changes in form and details may be made therein without departing from the scope of the following claims.

What is claimed is:

1. A memory module operating in response to commands communicated from a memory controller, the memory module comprising:
a memory chip mounted on a module substrate; and
a buffer chip mounted on the module substrate, wherein the buffer chip provides a hidden refresh command controlling execution of a refresh operation by the memory chip and during execution of the refresh operation provides a wait signal indicating execution of the refresh operation to the memory controller,
wherein the refresh operation is executed by the memory chip in response to the hidden refresh command independent of command communicated from the memory controller.

2. The memory module of claim 1, wherein the wait signal is communicated to the memory controller via a wait signal pin allocated on the module substrate for communication of only the wait signal.

3. The memory module of claim 1, wherein the wait signal is communicated to the memory controller via a data input/output pin allocated on the module substrate for communication of data during read/write operations.

4. The memory module of claim 1, wherein the wait signal is generated after a refresh latency period that begins when an active command is received by the buffer chip from the memory controller during execution of the refresh operation.

5. The memory module of claim 1, wherein the wait signal is a command identification signal indicating that execution of an active command communicated by the memory controller to the buffer chip during execution of the refresh operation may be delayed.

6. The memory module of claim 5, wherein the active command is a read command and the command identification signal is communicated to the memory controller after read data is output via a data input/output pin in response to the read command.

7. The memory module of claim 1, further comprising:
at least one temperature sensor that generates temperature information related to the memory module,
wherein the buffer chip changes a refresh period for refresh operation in accordance with the temperature information.

8. The memory module of claim 7, wherein each of the memory chips comprises a temperature sensor, and the buffer chip receives temperature information from the temperature sensors.

9. A memory system, comprising:
a memory module including a buffer chip and memory chips mounted on a module substrate; and
a memory controller that controls execution of read/write operations by the memory chips in response to commands communicated from the memory controller to the buffer chip,
wherein the buffer chip provides a hidden refresh command controlling execution of refresh operations by the memory chips, and during execution of the refresh operations the buffer chip provides a wait signal indicating execution of the refresh operations to the memory controller, the refresh operation being executed by the memory chips in response to the hidden refresh command independent of commands communicated from the memory controller.

10. The memory system of claim 9, wherein the memory controller is connected to the buffer chip via a data bus configured to communicate data signals between the memory controller and the buffer chip, and a control bus configured to communicate at least one of a command, an address and a control signal from the memory controller to the buffer chip.

11. The memory system of claim 9, wherein the memory controller is connected to the buffer chip via a control bus configured to communicate at least one of a command, an address and a control signal from the memory controller to the buffer chip, and
the memory controller is connected to the memory chips via a data bus configured to communicate data signals between the memory controller and the respective memory chips.

12. The memory system of claim 11, further comprising:
data buffers respectively disposed along the data bus between a memory chip and the memory controller.

13. The memory system of claim 9, wherein the wait signal is generated by the buffer chip after a refresh latency period that begins when an active command is received from the memory controller during execution of the refresh operation.

14. The memory system of claim 13, wherein the wait signal is a command identification signal indicating that execution of the active command may be delayed.

15. The memory system of claim 14, wherein the active command is a read command and the command identification signal is communicated to the memory controller after read data is output in response to the read command.

16. The memory system of claim 13, wherein the memory controller communicates a retry of the active command to the buffer chip in response to the wait signal only after a delay that is greater than a period equal to a normal refresh time for memory cells of the memory chips.

17. The memory system of claim 16, wherein the delay is equal to a sum of a refresh time required to refresh a memory cell and a /RAS to /CAS delay time.

18. A memory module comprising:
memory chips mounted on a module substrate; and
a buffer chip mounted on the module substrate and configured to communicate a hidden refresh command controlling refresh operations for the memory chips, wherein refresh of a weak cell row among the memory chips is performed in accordance with a period that is shorter than a normal refresh period associated with the refresh operations, and the refresh operation is executed by the memory chips in response to the hidden refresh command independent of commands communicated from the memory controller.

19. The memory module of claim 18, wherein the buffer chip stores weak cell information identifying a number of weak cell rows among the memory chips.

20. The memory module of claim 19, wherein each of the memory chips comprises:
an address storing unit that stores addresses for the weak cell rows;
a refresh address generation unit that generates a refresh address with respect to the refresh operation that is performed in response to a selection signal communicated from the buffer chip using a refresh counter performing a counting operation to generate the refresh row address, and an address change unit that selects the refresh row address or the weak cell row address.
